(19) United States
(12) Patent Application Publication
(10) Pub. No.: US 2019/0067115 A1
(43) Pub. Date: Feb. 28, 2019

(54) GATE CUT METHOD FOR REPLACEMENT METAL GATE

(71) Applicant: GLOBALFOUNDRIES INC., GRAND CAYMAN (KY)

(72) Inventors: Chanro PARK, Clifton Park, NY (US); Laertis ECONOMIKOS, Wappingers Falls, NY (US); Ruilong XIE, Schenectady, NY (US); Min Gyu SUNG, Latham, NY (US)

(73) Assignee: GLOBALFOUNDRIES INC., GRAND CAYMAN (KY)

(21) Appl. No.: 15/683,968

(22) Filed: Aug. 23, 2017

(51) Int. Cl. H01L 21/8234; H01L 27/088; H01L 21/768; H01L 29/66

(52) U.S. Cl. CPC H01L 21/823437; H01L 27/0886; H01L 21/76822; H01L 21/823481; H01L 21/823431; H01L 21/823468; H01L 29/66545

(57) ABSTRACT

A method of manufacturing a FinFET structure involves forming a gate cut within a sacrificial gate layer and backfilling the gate cut opening with an etch selective dielectric later. Lateral etching of the dielectric layer after removing remaining portions of the sacrificial gate can be used to increase the distance between the gate cut (isolation) structure and an adjacent fin relative to methods that do not perform a step of trimming the dielectric layer.

### BACKGROUND

The present application relates generally to semiconductor devices, and more specifically to methods for manufacturing fin field effect transistors.

Fully-depleted devices such as fin field effect transistors (FinFETs) are candidates to enable scaling of next generation gate lengths to 14 nm and below. Fin field effect transistors (FinFETs) present a three-dimensional architecture where the transistor channel is raised above the surface of a semiconductor substrate, rather than locating the channel at or just below the surface. With a raised channel, the gate can be wrapped around the sides of the channel, which provides improved electrostatic control of the device.

The manufacture of FinFETs typically leverages a self-aligned process to produce extremely thin fins, e.g., 20 nm wide or less, on the surface of a substrate using selective-etching techniques. A gate structure is then deposited to contact multiple surfaces of each fin to form a multi-gate architecture.

The gate structure may be formed using a gate-first or a gate-last fabrication process. A gate-last process, such as a replacement metal gate (RMG) process, utilizes a sacrificial or dummy gate, which is typically replaced by a functional gate after device activation, i.e., after dopant implantation into source/drain regions of the fins and an associated drive-in anneal, in order to avoid exposing the functional gate materials to the thermal budget associated with activation.

Prior to removing the sacrificial gate and forming a functional gate structure, a gate cut module may be used to sever (i.e., segment) the sacrificial gate in order to define and isolate plural adjacent devices. In association with such a process, portions of the sacrificial gate are removed to form openings that are backfilled with an etch selective dielectric material that provides a barrier between adjacent functional gates following removal and replacement of the remaining sacrificial gate material.

In various processes, such as a “cut first” approach, where the gate cut module precedes the formation of epitaxial source/drain junctions, unintended exposure of the sacrificial gate due to over-etching may create a growth surface for superfluous epitaxial material, resulting in the formation of epitaxial nodules. This additional epitaxial material may cause a short circuit, e.g., between the later-formed gate and a source/drain of a device.

With a conventional “cut last” approach, on the other hand, the proximity of the backfilled layer to an adjacent fin may result in insufficient space for deposition of a complete functional gate structure (e.g., gate dielectric and gate conductor layers), as these or other intermediate layers used during processing may pinch-off rather than form a desired conformal architecture. The associated defects adversely affect reliability and yield.

### SUMMARY

Accordingly, it would be beneficial to provide a method for defining a sacrificial gate structure at critical dimensions with a high degree of accuracy and precision, especially a gate structure that enables formation of a functional replacement metal gate at advanced nodes without altering design rules or otherwise compromising real estate.

Disclosed is a gate cut scheme that may be used in conjunction with a replacement metal gate (RMG) process flow for manufacturing fin field effect transistors (FinFETs) where the gate cut and the associated backfill include the formation of a gate cut region having a critical dimension, e.g., along a segmentation direction of the sacrificial gate, that is less than dimensions that are currently obtainable. Partial removal, i.e., trimming, of the backfilled dielectric layer produces a thinner cut region and defines a correspondingly wider gap between the remaining gate cut dielectric and an adjacent fin.

In accordance with embodiments of the present application, a method of forming a semiconductor structure includes forming a sacrificial gate over a plurality of semiconductor fins, and forming a gate cut opening that extends through the sacrificial gate, where a sidewall of the gate cut opening is laterally spaced away from a first one of the fins by a first distance.

The method further includes depositing a dielectric layer into the gate cut opening, selectively removing the sacrificial gate with respect to the dielectric layer, and laterally recessing a sidewall of the dielectric layer to form a gap between the dielectric layer and the first one of the fins, such that a width of the gap is greater than the first distance.

According to further embodiments, a semiconductor structure includes a fin disposed over a semiconductor substrate, a shallow trench isolation layer disposed over the substrate and laterally adjacent to the fin, and a gate stack disposed over the fin and above the shallow trench isolation layer, wherein the gate stack includes a gate dielectric formed over the fin and a gate conductor formed over the gate dielectric.

A dielectric layer is laterally spaced from the fin and contacts the gate stack, which fills a gap between the dielectric layer and the fin where the gap includes a recessed region within the shallow trench isolation layer.

### BRIEF DESCRIPTION OF SEVERAL VIEWS OF THE DRAWINGS

The following detailed description of specific embodiments of the present application can be best understood when read in conjunction with the following drawings, where like structure is indicated with like reference numerals and in which:

FIG. 1 is a simplified top down plan view schematic diagram of a FinFET architecture according to various embodiments;

FIG. 2A is a cross-sectional view of a FinFET device at an intermediate stage of fabrication taken normal to a length direction of a fin array showing a layer of amorphous silicon defining a sacrificial gate and an extended gate (EG) oxide layer formed over the fins and a hard mask formed over the layer of amorphous silicon;

FIG. 2B is a cross-sectional view transverse to the image of FIG. 2A taken between adjacent fins showing an interlayer dielectric and the amorphous silicon and EG oxide layer within a gate cut region;

FIG. 3A shows patterning and etching of the sacrificial gate to form a gate cut opening;

FIG. 3B shows removal of the sacrificial gate and EG oxide layer from within the gate cut region to form gate cut openings;

FIG. 4A depicts the deposition and planarization of a dielectric layer within the gate cut opening;

FIG. 4B depicts the deposition and planarization of a dielectric layer within the gate cut openings;

FIG. 5A shows selective removal of the sacrificial gate and the retention of a dielectric spacer within the gate cut region;

FIG. 5B shows the dielectric layer planarized with respect to the interlayer dielectric;

FIG. 6A depicts trimming of the dielectric spacer using a selective isotropic etch;

FIG. 6B shows etching of the dielectric layer with respect to the interlayer dielectric;

FIG. 7A depicts stripping of the EG oxide layer and the formation of a divot within the shallow trench isolation immediately adjacent to the dielectric layer;

FIG. 7B shows the interlayer dielectric and dielectric layer between adjacent fins following removal of the EG oxide layer;

FIG. 8A shows the deposition of a replacement gate architecture and capping layer over the fins;

FIG. 8B shows the interlayer dielectric and dielectric layer between adjacent fins following formation of the replacement gate;

FIG. 9A shows patterning and etching of the sacrificial gate selective to the EG oxide layer to form a gate cut opening according to further embodiments;

FIG. 9B shows removal of the sacrificial gate from within the gate cut region to form gate cut openings;

FIG. 10A depicts the deposition and planarization of a dielectric layer within the gate cut opening and over the EG oxide layer;

FIG. 10B depicts the deposition and planarization of a dielectric layer within the gate cut openings;

FIG. 11A shows selective removal of the sacrificial gate and the retention of a dielectric spacer within the gate cut region;

FIG. 11B shows the dielectric layer planarized with respect to the interlayer dielectric;

FIG. 12A depicts trimming of the dielectric spacer using a selective isotropic etch;

FIG. 12B shows etching of the dielectric layer with respect to the interlayer dielectric;

FIG. 13A depicts stripping of exposed portions of the EG oxide layer;

FIG. 13B shows the interlayer dielectric and dielectric layer between adjacent fins following removal of exposed portions of the EG oxide layer;

FIG. 14A shows the deposition of a replacement gate architecture and capping layer over the fins;

FIG. 14B shows the interlayer dielectric and dielectric layer between adjacent fins following formation of the replacement gate;

FIG. 15A is a cross-section of a FinFET device at an intermediate stage of fabrication taken normal to a length direction of a fin array showing an amorphous silicon layer, sacrificial barrier layer and extended gate (EG) oxide layer formed over the fins and a hard mask formed over the amorphous silicon layer;

FIG. 15B is a cross-sectional view transverse to the image of FIG. 15A taken through a fin showing the hard mask, amorphous silicon layer, sacrificial barrier layer and EG oxide layer formed over a fin;

FIG. 16A shows the structure of FIG. 15A after patterning and etching the amorphous silicon layer to form a sacrificial gate;

FIG. 16B shows the structure of FIG. 15B following patterning and etching steps to form a sacrificial gate straddling the fin;

FIG. 17A shows the structure of FIG. 16A after the deposition of sidewall spacers over the sacrificial gate and the formation of epitaxial source/drain junctions over source/drain regions of the fin;

FIG. 17B depicts the deposition of sidewall spacers over adjacent sacrificial gates and the formation of epitaxial source/drain junctions over the fin within openings between the sacrificial gates;

FIG. 18A is a cross-sectional view of a FinFET device at an intermediate stage of fabrication taken normal to a length direction of a fin array showing a layer of amorphous silicon defining a sacrificial gate, a sacrificial barrier layer and an extended gate (EG) oxide layer formed over the fins and a hard mask formed over the layer of amorphous silicon;

FIG. 18B is a cross-sectional view transverse to the view of FIG. 18A taken between adjacent fins showing an interlayer dielectric, and the amorphous silicon layer, sacrificial barrier layer and EG oxide layer within a gate cut region;

FIG. 19A shows patterning and etching of the sacrificial gate to form a gate cut opening;

FIG. 19B shows removal of the sacrificial gate and sacrificial barrier layer from within the gate cut region to form gate cut openings;

FIG. 20A depicts the deposition and planarization of a dielectric layer within the gate cut opening;

FIG. 20B depicts the deposition and planarization of a dielectric layer within the gate cut openings;

FIG. 21A shows selective removal of the sacrificial gate and the retention of a dielectric spacer within the gate cut region;

FIG. 21B shows the dielectric layer planarized with respect to the interlayer dielectric;

FIG. 22A depicts trimming of the dielectric spacer using a selective isotropic etch to form a thinned dielectric spacer overlying the EG oxide layer within the gate cut region according to various embodiments;

FIG. 22B shows partial removal of the dielectric layer with respect to the interlayer dielectric;

FIG. 23A shows etching of the exposed EG oxide layer;

FIG. 23B shows the interlayer dielectric and dielectric layer between adjacent fins following removal of exposed portions of the EG oxide layer;

FIG. 24A shows the deposition of a replacement gate architecture and capping layer over the fins; and

FIG. 24B shows the interlayer dielectric, dielectric layer and capping layer between adjacent fins following deposition of the replacement gate.

### DETAILED DESCRIPTION

Reference will now be made in greater detail to various embodiments of the subject matter of the present application, some embodiments of which are illustrated in the accompanying drawings. The same reference numerals will be used throughout the drawings to refer to the same or similar parts.

Disclosed are FinFET structures and methods of manufacturing FinFET structures, and more particularly methods where segmentation of a sacrificial gate in a region between adjacent fins that are each straddled by the sacrificial gate includes etching the sacrificial gate to form a gate cut opening and backfilling the gate cut opening with a dielectric layer. After removing the remaining sacrificial gate, the method further includes etching the dielectric layer so as to decrease at least one lateral dimension thereof. In various embodiments, the dielectric layer is etched to decrease its width along a direction substantially perpendicular to a length direction of the fins.

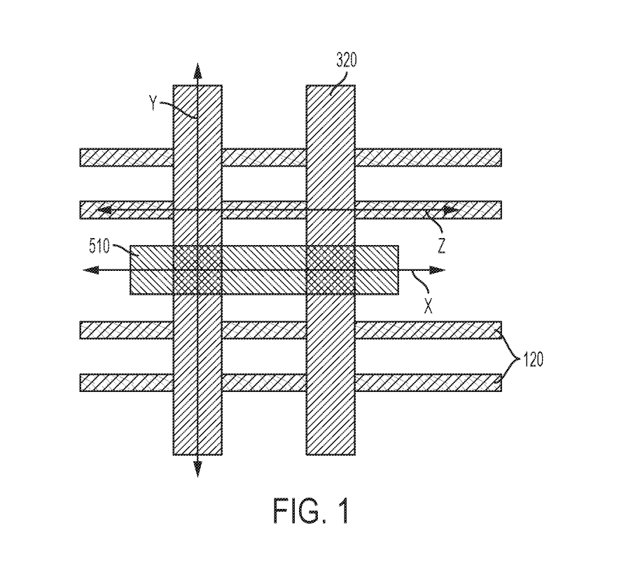

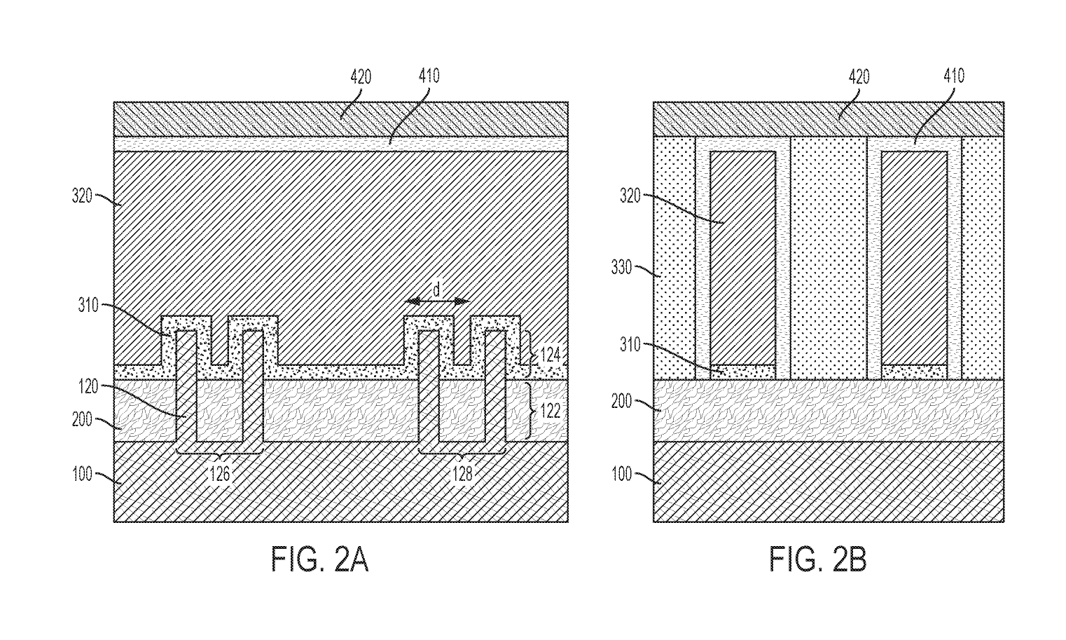

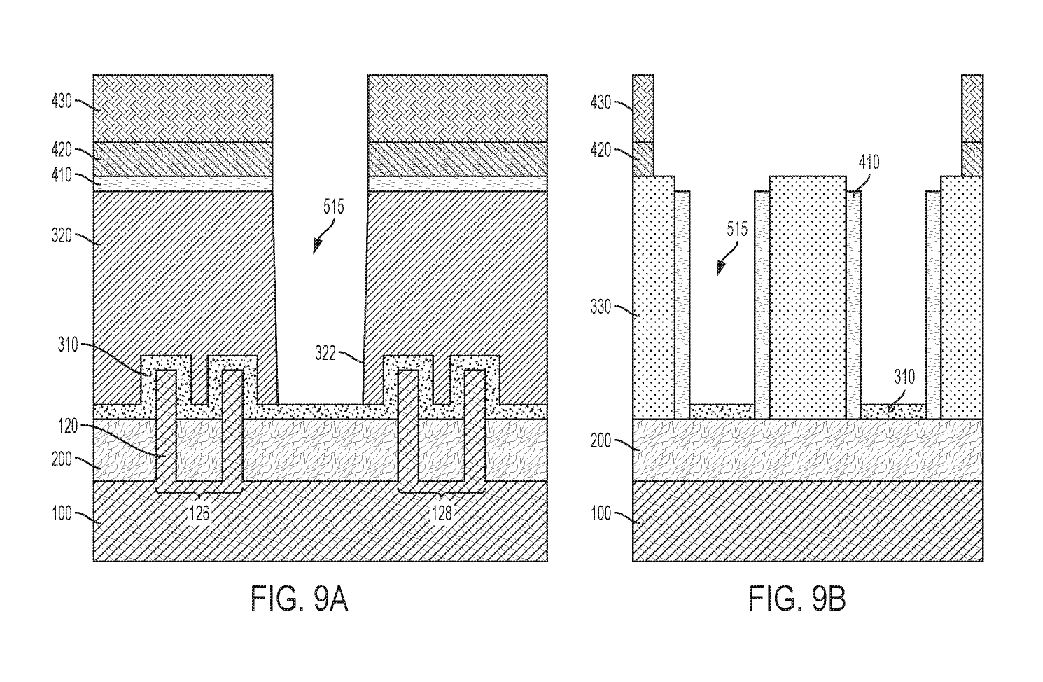

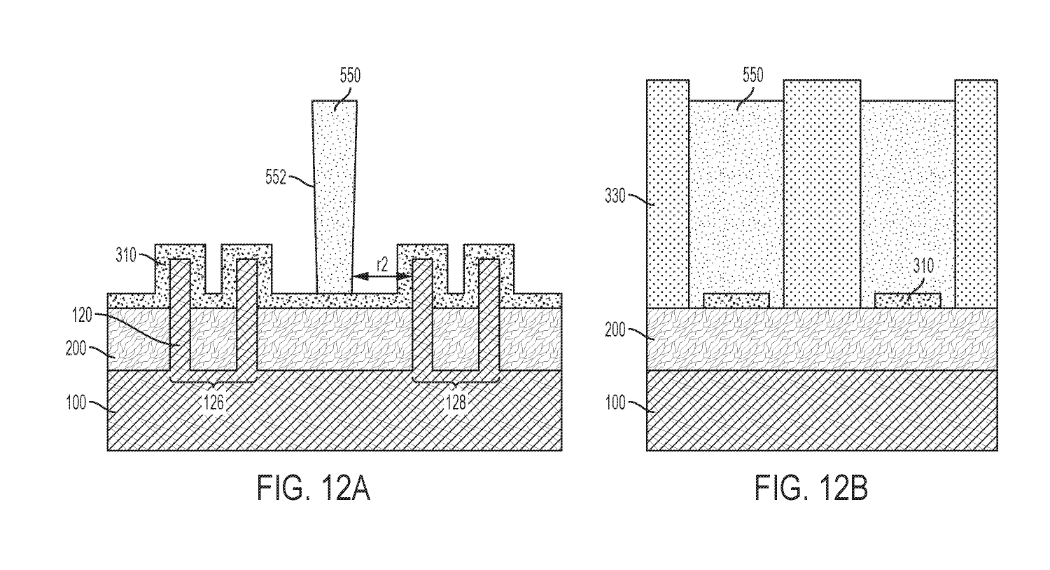

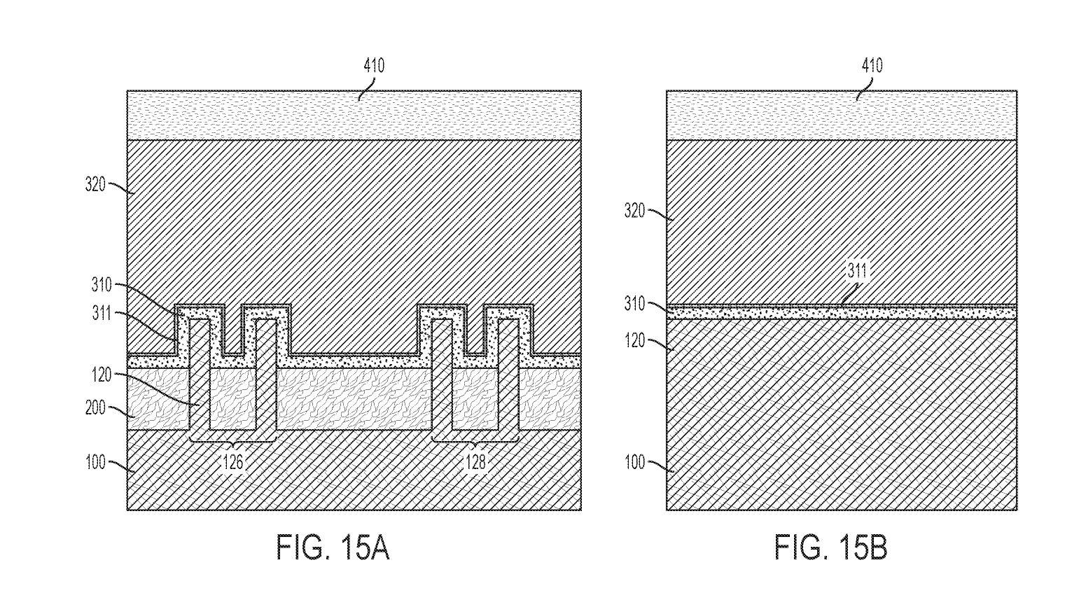

Segmentation includes providing a gate cut opening that extends through the sacrificial gate. The dielectric layer, which at least partially fills the gate cut opening and is disposed proximate to an adjacent fin, may be at least partially removed during subsequent processing to increase the width of an opening between the dielectric layer and the fin into which a functional gate structure, including gate dielectric and gate conductor layers, can be deposited. As used herein, a “functional gate” refers to a structure used to control output current (i.e., the flow of carriers through a channel) of a semiconductor device using an electrical field or, in some instances, a magnetic field, and includes a gate dielectric and a gate conductor. Various embodiments related to the formation of such FinFET structures are described herein with reference to FIGS. 1-24. A first embodiment is illustrated in connection with FIGS. 2-8, a second embodiment is illustrated with reference to FIGS. 9-14, and a third embodiment is described with reference to FIGS. 15-24.

A simplified top down plan view schematic diagram of a FinFET architecture is shown in FIG. 1. Plural semiconductor fins 120 are arrayed over a semiconductor substrate (not shown) and a pair of sacrificial gates 320 are arranged orthogonal to and straddle the fins 120. A gate cut region 510 is located between a pair of adjacent fins, and identifies the portions of the sacrificial gates 320 that are to be cut. Parallel reference lines X-X and Z-Z are oriented parallel to a length direction of the fins 120, with line X-X taken through the gate cut region 510 between the fins 120 and line Z-Z taken along the length of a fin, while reference line Y-Y is oriented perpendicular to the fin length through a sacrificial gate 320.

Mutually transverse cross-sectional views of a FinFET device at an intermediate stage of fabrication are shown in FIG. 2A and FIG. 2B. FIG. 2A is taken along the line Y-Y of FIG. 1, while FIG. 2B is taken along the line X-X. The exemplary structure includes a semiconductor substrate 100 and a plurality of semiconductor fins 120 arrayed over the substrate 100. The semiconductor fins 120 are arranged in parallel and are laterally isolated from each other within sub-fin region 122 by a shallow trench isolation layer 200. The fins 120 extend above shallow trench isolation layer (STI) layer 200 and form an active device region 124. According to various embodiments, a first group 126 of fins 120 may be configured to form an n-type FET (NFET), while a second group 128 of fins 120 may be configured to form a p-type FET (PFET).

Substrate 100 may include a semiconductor material such as silicon, e.g., single crystal Si or polycrystalline Si, or a silicon-containing material. Silicon-containing materials include, but are not limited to, single crystal silicon germanium (SiGe), polycrystalline silicon germanium, silicon doped with carbon (Si:C), amorphous Si, as well as combinations and multi-layers thereof. As used herein, the term “single crystal” denotes a crystalline solid, in which the crystal lattice of the entire solid is substantially continuous and substantially unbroken to the edges of the solid with substantially no grain boundaries.

The substrate 100 is not limited to silicon-containing materials, however, as the substrate 100 may comprise other semiconductor materials, including Ge and compound semiconductors, including III-V compound semiconductors such as GaAs, InAs, GaN, GaP, InSb, ZnSe, and ZnS, and II-VI compound semiconductors such as CdSe, CdS, CdTe, ZnSe, ZnS and ZnTe.

Substrate 100 may be a bulk substrate or a composite substrate such as a semiconductor-on-insulator (SOI) substrate that comprises, from bottom to top, a handle portion, an isolation layer (e.g., buried oxide layer), and a semiconductor material layer.

Substrate 100 may have dimensions as typically used in the art and may comprise, for example, a semiconductor wafer. Example wafer diameters include, but are not limited to, 50, 100, 150, 200, 300 and 450 mm. The total substrate thickness may range from 250 microns to 1500 microns, although in particular embodiments the substrate thickness is in the range of 725 to 775 microns, which corresponds to thickness dimensions commonly used in silicon CMOS processing. The semiconductor substrate 100 may comprise (100)-oriented silicon or (111)-oriented silicon, for example.

In various embodiments, fins 120 comprise a semiconductor material such as silicon, and may be formed by patterning and then etching the semiconductor substrate 100, e.g., a top portion of the semiconductor substrate. In several embodiments, the fins 120 are etched from, and therefore contiguous with the semiconductor substrate 100. For instance, fins 120 may be formed using a sidewall image transfer (SIT) process as known to those skilled in the art.

In certain embodiments, the fins 120 can have a width of 5 nm to 20 nm, a height of 40 nm to 150 nm, and a pitch of 20 nm to 100 nm, although other dimensions are also contemplated. Fins 120 may be arrayed on the substrate at a regular intrafin spacing or pitch (d). As used herein, the term “pitch” refers to the sum of the fin width and the spacing between neighboring fins. In example embodiments, the fin pitch (d) may be within a range of 20 to 100 nm, e.g., 20, 30, 40, 50, 60, 70, 80, 90 or 100 nm, including ranges between any of the foregoing values, although smaller and larger pitch values may be used.

As shown in the illustrated embodiment, upper portions of the fins 120 (i.e., within active device region 124) may be coated with a thin conformal oxide layer, which is referred to herein as an extended gate or EG oxide layer 310. The EG oxide layer 310 may comprise silicon dioxide, for example, and may be formed over the fins within the subfin region 122 (not shown) and/or the active device region 124. The EG oxide layer 310 may have a thickness of 2 to 3 nm. During the course of manufacturing the FinFET device, the EG oxide layer 310 may be stripped from source and drain regions of the fins and/or channel regions of the fins, or may be retained within these regions.

Shallow trench isolation (STI) layer 200 may be used to provide electrical isolation between the fins 120 and between adjacent devices as is needed for the circuit(s) being formed. An STI process for FinFET devices involves creating isolation trenches in the semiconductor substrate 100 through an anisotropic etch process. The isolation trench between each adjacent fin may have a relatively high aspect ratio (e.g., ratio of the depth of the isolation trench to its width). A dielectric filler material, such as silicon dioxide, is deposited into the isolation trenches, for example, using an enhanced high aspect ratio process (eHARP) to fill the isolation trenches. The deposited dielectric material may then be polished by a chemical-mechanical polishing (CMP) process that removes the excess dielectric material and creates a planar STI structure. The planarized oxide is then etched back to form a recessed, uniformly thick oxide isolation layer 200 between the fins 120, where upper sidewalls of the fins 120, i.e., sidewalls within active device region 124, can be exposed for further processing.

Referring still to FIG. 2A and FIG. 2B, a sacrificial gate layer 320 is disposed over and straddles the fins 120. The sacrificial gate layer 320 is formed over the fins 120 and over the STI layer 200, i.e., over substrate 100. The sacrificial gate layer 320 may comprise a patterned layer of amorphous silicon (a-Si), for example.

Amorphous elemental silicon can be deposited using chemical vapor deposition, such as low pressure chemical vapor deposition (LPCVD) at temperatures ranging from 450° C. to 700° C. Silane (SiH₄) can be used as the precursor for CVD silicon deposition. The sacrificial gate layer 320 may have a thickness sufficient to completely cover the fins. For instance, a thickness of sacrificial gate layer 320 may range from 50 to 200 nm, e.g., 50, 75, 100, 125, 150, 175 or 200 nm, including ranges between any of the foregoing values, although lesser and greater thicknesses may be used. A CMP process may be used to planarize a top surface of the sacrificial gate layer 320.

“Planarization” refers to a material removal process that employs at least mechanical forces, such as frictional media, to produce a substantially two-dimensional surface. A planarization process may include chemical mechanical polishing (CMP) or grinding. Chemical mechanical polishing (CMP) is a material removal process that uses both chemical reactions and mechanical forces to remove material and planarize a surface.

Optionally, a sacrificial oxide layer (not shown) may be deposited over the sacrificial gate layer 320 prior to a CMP step and then subsequently removed during the CMP step in order to enhance planarization. In certain embodiments, a non-selective etch such as a reactive ion etch (RIE) of the post-planarized sacrificial gate layer 320 may be used to define the thickness of the sacrificial gate layer 320.

As will be described in further detail below, sacrificial gate layer 320 is adapted to be patterned and provide a structure for a replacement metal gate (RMG) module used to define a three-dimensional gate architecture over the fins. Depending on the design requirements for the associated device, the number of fins underlying the sacrificial gate structures may vary from 2 to 100, although a greater number of fins may be used. An example structure that includes just four fins 120 is shown for clarity.

A gate hard mark 410 is formed over the sacrificial gate 320, i.e., over the top and sidewall surfaces of the sacrificial gate, and an interlayer dielectric (ILD) 330 is deposited over the gate hard mask 410 and between the sacrificial gates 320. The deposited ILD layer 330 may be polished to removes the excess ILD material and create a planarized structure. The gate hard mark 410 may serve as stop layer during such a polishing process. A gate cut hard mask 420 is then formed over the gate hard mask 410. The gate hard mask 410 and the gate cut hard mask 420 may independently comprise silicon nitride, boron nitride or SiOCN, for example.

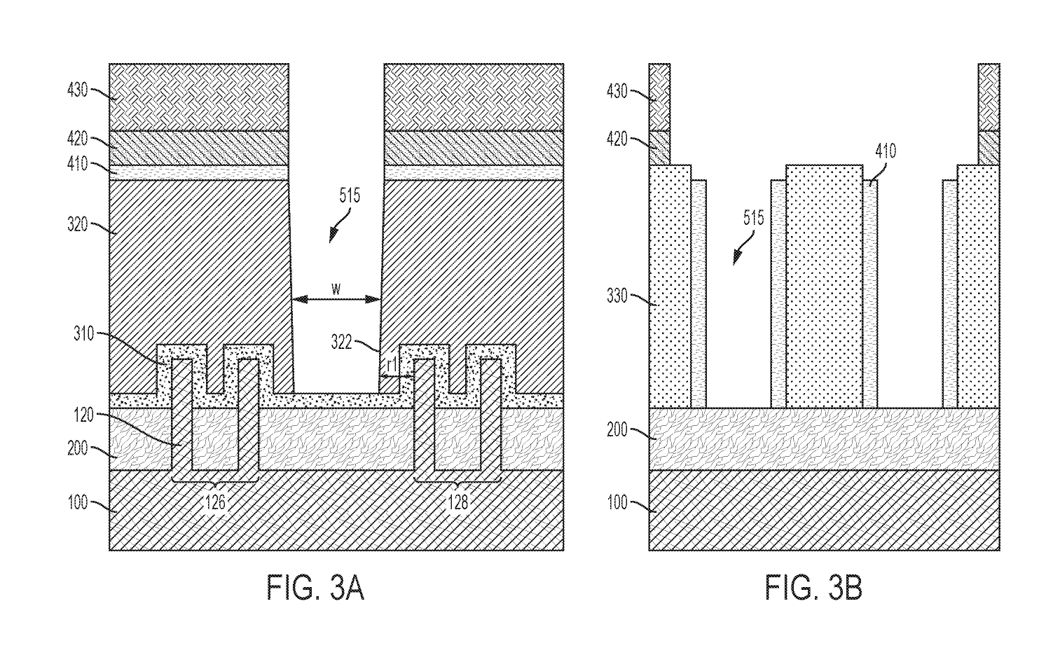

Referring to FIG. 3A and FIG. 3B, the sacrificial gate layer 320 is segmented, or cut, to define a gate cut opening 515 within the gate cut region 510. The gate cut opening 515 separates remaining portions of the sacrificial gate layer 320 into discrete device regions. According to various embodiments, the gate cut openings 515 are backfilled with a dielectric material in order to isolate the various sacrificial gate structures and hence the later-formed functional gates associated with respective devices. Independent transistors may be connected by local interconnection methods and/or back end of the line metallization layers to form integrated circuits, such as SRAM devices.

As shown in FIGS. 3A and 3B, gate cut opening 515 may be formed by directionally etching the sacrificial gate layer 320. In the illustrated embodiment, the gate cut opening 515 extends through the sacrificial gate layer 320 and the EG oxide layer 310 and exposes STI region 200. According to the current embodiment, the gate cut opening 515 is configured to expose a portion of the STI layer 200 between adjacent fins without exposing the fins themselves.

Gate cut opening 515 may be formed using patterning and etching processes known to those skilled in the art. The patterning process may comprise photolithography, for example, which includes forming a layer of photoresist material (not shown) atop one or more layers to be patterned. The photoresist material may include a positive-tone photoresist composition, a negative-tone photoresist composition, or a hybrid-tone photoresist composition. A layer of photoresist material may be formed by a deposition process such as, for example, spin-on coating.

The deposited photoresist is then subjected to a pattern of irradiation, and the exposed photoresist material is developed utilizing a conventional resist developer. The pattern provided by the patterned photoresist material is thereafter transferred into the sacrificial gate layer 320 utilizing at least one pattern transfer etching process.

The pattern transfer etching process is typically an anisotropic etch. In certain embodiments, a dry etching process such as, for example, reactive ion etching (RIE) can be used. In other embodiments, a wet chemical etchant can be used. In still further embodiments, a combination of dry etching and wet etching can be used.

Patterning and etching the sacrificial gate layer 320 to form gate cut openings 515 may including forming a lithography stack 430 over the sacrificial gate layer 320. A lithography stack 400 may include one or more of an optical planarization layer, an etch stop layer, an amorphous carbon layer, an adhesion layer, an oxide layer, and a nitride layer (not separately shown). Such layer(s) may be configured as known to those skilled in the art to provide a suitable masking layer to pattern and etch the sacrificial gate layer 320.

A gate cut opening 515 may have areal dimensions (length and width) that independently range from 15 to 50 nm, although lesser and greater dimensions may be used. According to various embodiments, the areal dimensions of the as-formed gate cut openings 515 are within lithography process windows for forming such structures, and enable the gate cut openings 515 to be defined with substantially vertical sidewalls. As used herein, “substantially vertical” sidewalls deviate from a direction normal to a major surface of the substrate by less than 5°, e.g., 0, 1, 2, 3, 4, or 5°, including ranges between any of the foregoing values. In certain embodiments, the initial width (w) of the gate cut opening 515 is 15 to 50 nm, e.g., 15, 20, 25, 30, 35, 40, 45 or 50 nm, including ranges between any of the foregoing values. As shown in FIG. 3A, the width (w) of the gate cut opening 515 is defined along a direction perpendicular to a length direction of the fins 120.

In various embodiments, a distance (r1) between the sidewall 322 of the gate cut opening 515 and an adjacent fin may be less than 20 nm, e.g., 12, 14, 16 or 18 nm, including ranges between any of the foregoing values. Decreasing the distance (r1) beneficially impacts the achievable density of devices. However, decreasing the distance between adjacent structures may introduce design and processing challenges. As will be appreciated, such challenges may include the deposition of a functional gate architecture, including a gate dielectric layer, gate conductor layer and conductive fill material within the available geometry, e.g., conformally into the space between the sidewall of the gate cut and a neighboring fin. Using the presently-disclosed methods, a structure can be formed having an increased distance between the sidewall of a gate cut dielectric and an adjacent fin without altering the design rules for the overall device.

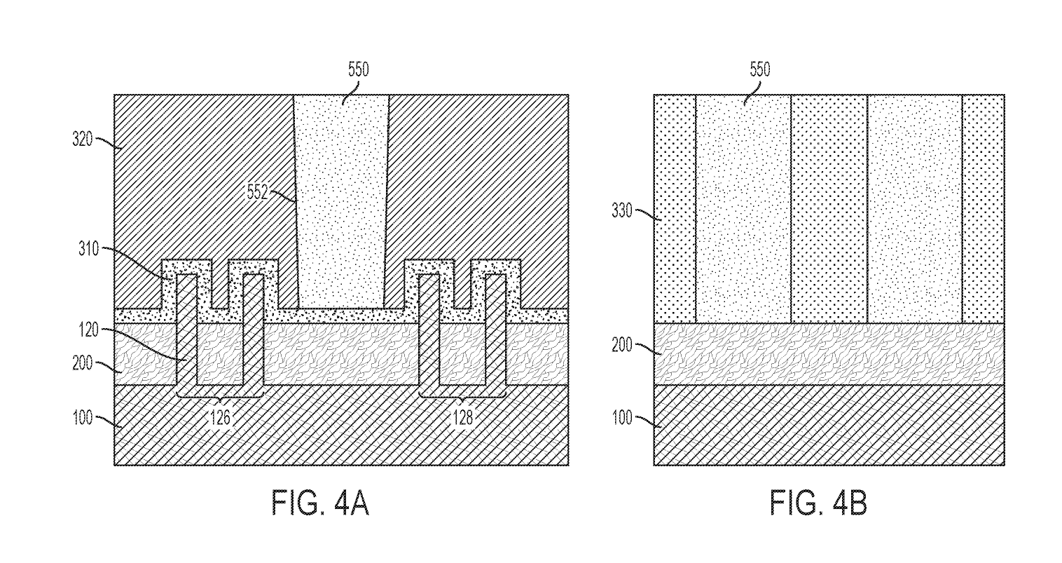

Referring to FIG. 4A and FIG. 4B, a dielectric layer 550 is deposited to substantially fill the gate cut opening 515. The dielectric fill layer 550 may be formed by atomic layer deposition (ALD) or chemical vapor deposition (CVD) and may comprise a material such as silicon nitride. In an exemplary ALD process, for instance, a silicon-containing precursor and a nitrogen-containing precursor are deposited in succession and reacted to form the nitride fill layer.

A chemical mechanical polishing step may be used to selectively remove the overburden following deposition of the dielectric fill layer 550 and produce a planarized structure. The sacrificial gate layer 320 may serve as a CMP etch stop during removal of the excess fill layer material, such that the CMP step removes the lithography stack 430, gate cut hard mask 420 and portions of the gate hard mask 410 disposed over the ILD layer 330.

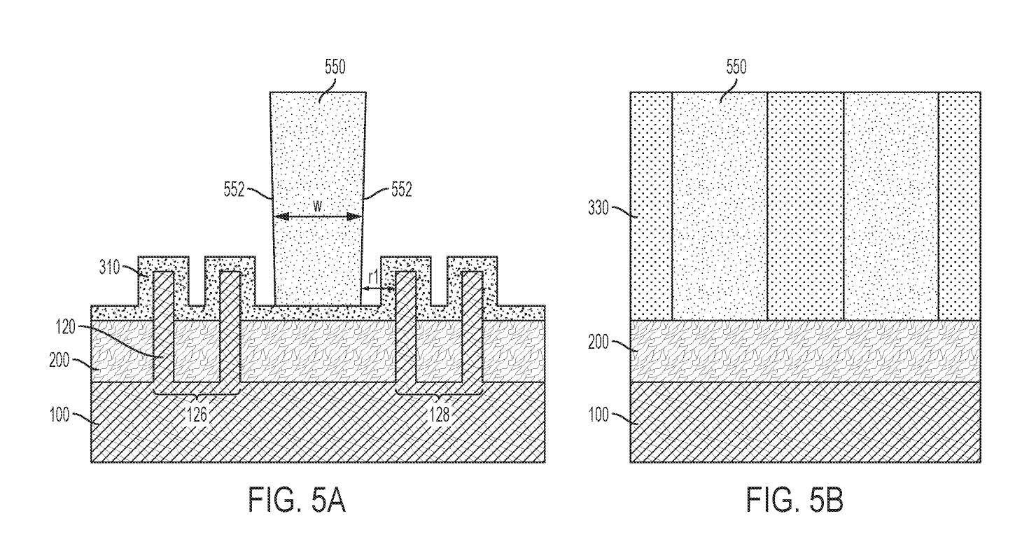

Thereafter, referring to FIG. 5A and FIG. 5B, a selective etching step is used to remove the sacrificial gate layer 320. In embodiments where the sacrificial gate layer 320 comprises amorphous silicon, the sacrificial gate layer 320 can be etched and removed selectively with respect to silicon dioxide and silicon nitride using a wet etch chemistry comprising, for example, phosphoric acid, hydrofluoric acid and nitric acid. Following removal of the sacrificial gate 320, dielectric layer 550 remains within the gate cut region 510. Dielectric layer 500 may have a width (w). As seen with reference to FIG. 5A, a distance (r1) between a sidewall 552 of dielectric layer 550 and an adjacent fin 120 may be less than 20 nm.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, 5:1, 10:1 or 20:1.

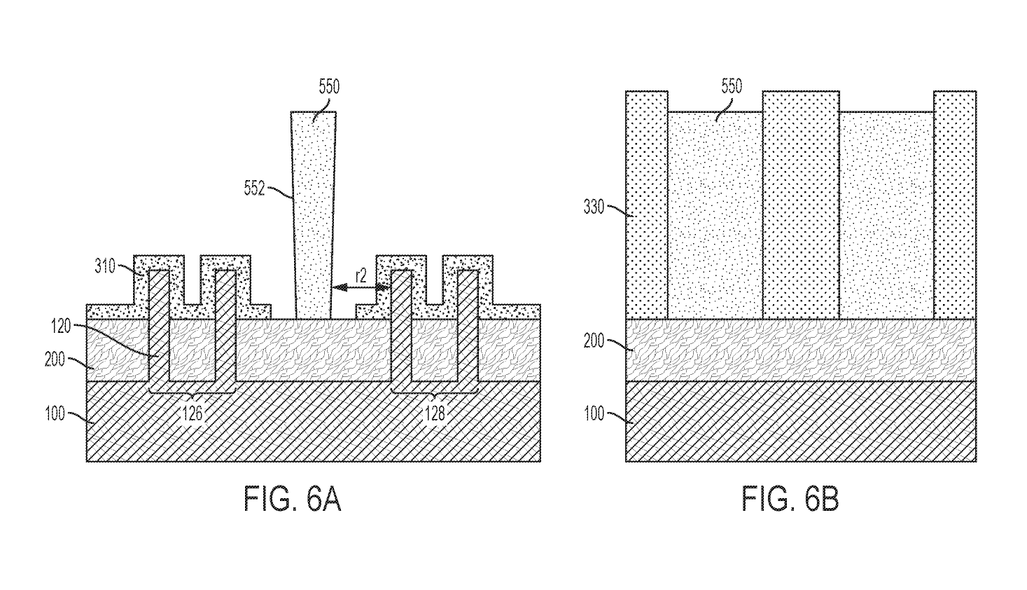

Referring to FIG. 6A and FIG. 6B, an isotropic etching step is used to etch the exposed dielectric layer 550. The isotropic etching step is adapted to decrease at least one lateral dimension of the dielectric layer 550. As used herein, the terms “lateral,” “laterally” and the like refer to directions taken parallel to a major surface of the substrate. Thus, in various embodiments, the isotropic etch removes material from the exposed sidewall surfaces 552 of the dielectric layer 550 proximate to the adjacent fins 120, resulting in a distance (r2) between the sidewall surfaces 552 of the dielectric layer 550 and each respective adjacent fin 120, where r2>r1. The isotropic etch of the dielectric layer 550 may be selective to the EG oxide layer 310. In some embodiments, the isotropic etch of the dielectric layer 550 may be selective to the gate hard mask 410.

Etching may remove as much as 70% of the as-deposited width (w) of the dielectric layer 550, e.g., 20, 30, 40, 50, 60 or 70%, including ranges between any of the foregoing values. For instance, and by way of example, an initial thickness of the dielectric layer 550 within the gate cut opening may be 16 nm, and a final thickness of the dielectric layer may be 5 nm. In such an example, the distance from a sidewall 552 of the dielectric layer 550 to an adjacent fin 120 may be 5.5 nm greater than the original (i.e., pre-lateral etch) distance from the sidewall 552 of the dielectric layer 550 to the fin 120. i.e., r2=r1+5.5 nm. In certain embodiments, the lateral etch of the dielectric layer 550 may remove 2 to 10 nm from each exposed sidewall, e.g., 2, 4, 6, 8 or 10 nm, including ranges between any of the foregoing values. This corresponding increase in the distance between the semiconductor fin 120 and the gate cut dielectric 550 provides additional space for deposition of a gate architecture over the fin immediately adjacent to the gate cut.

In various embodiments, the remaining thickness of the dielectric layer 550 is effective to electrically isolate a functional gate formed on one side of the dielectric layer 550 from a functional gate formed on the other side of the dielectric layer 550.

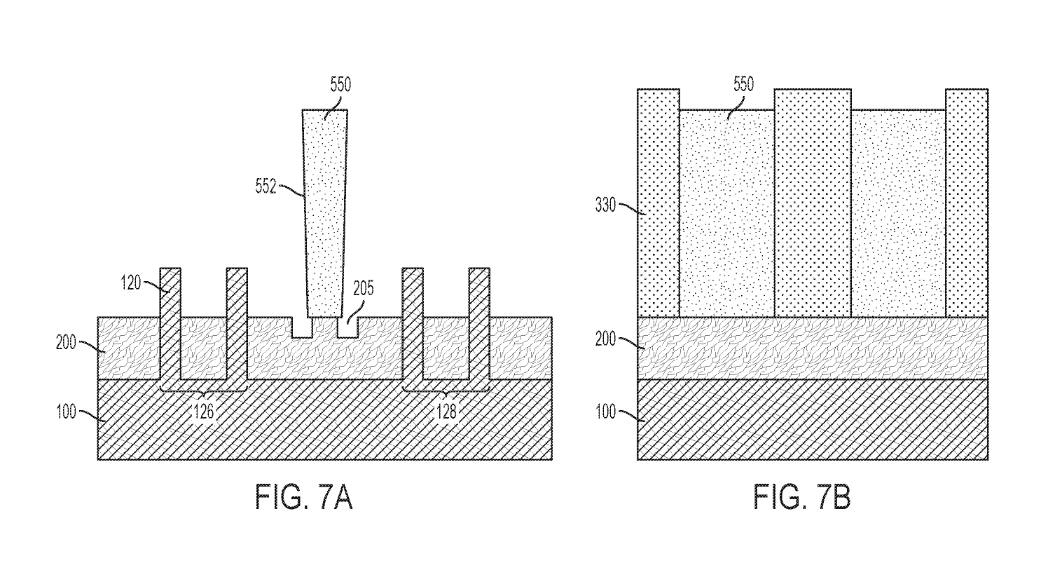

Referring to FIG. 7A and FIG. 7B, following removal of the sacrificial gate layer 320, and trimming of the dielectric layer 550, a selective oxide etch can be used to remove the EG oxide layer 210 from over the fins. In various embodiments, the EG oxide layer 310 is removed using a buffered oxide etch, which can include a wet etching process or a vapor etching process that uses a buffered hydrofluoric acid (BHF) solution. By way of example, the BHF solution may comprise hydrofluoric acid (HF), ammonium fluoride (NH₄F) and water (H₂O). In a particular embodiment, the BHF solution contains 0.5 to 10 vol. % hydrofluoric acid, 30 to 50 vol. % ammonium fluoride, and 40 to 60 vol. % water. The BHF solution selectively etches the EG oxide layer 310, and may etch the shallow trench isolation layer 200, without etching the other layers of the structure.

In certain embodiments, referring to FIG. 7A, stripping of the EG oxide layer 310 may remove portions of STI layer 200 immediately adjacent to dielectric layer 550. That is, portions of the STI layer 200 initially beneath the dielectric layer 550 may become exposed following the lateral etch of the dielectric layer 550, resulting in the formation of a divot 205 within the STI layer 200 laterally adjacent to and beneath dielectric layer 550.

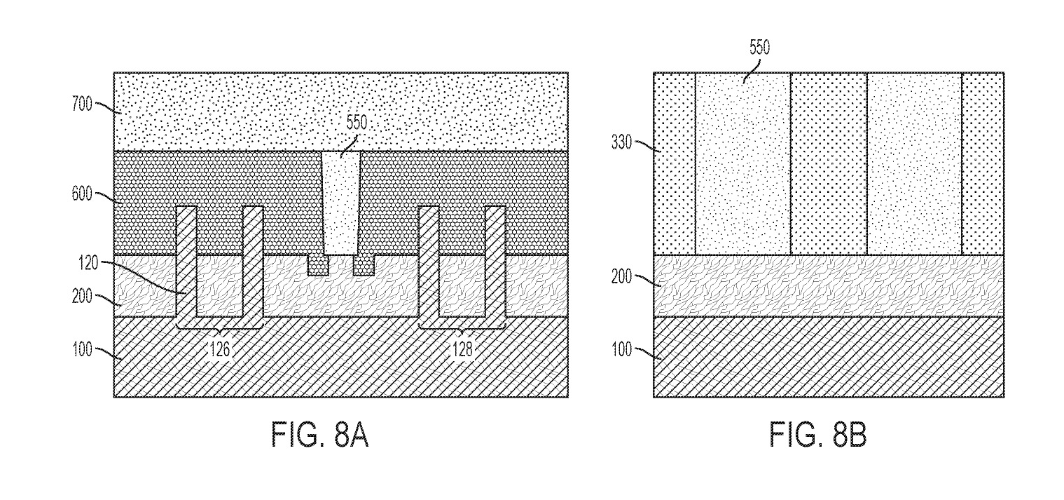

Referring to FIG. 8A and FIG. 8B, a functional gate architecture 600 and overlying capping layer 700 are formed over the fins 120 within the active device region 124. The functional gate architecture includes a gate dielectric layer and one or more gate conductor layers, which are deposited in succession. For simplicity, the individual layers of the gate architecture 600 are not separately shown.

The gate dielectric may be a conformal layer that is formed over exposed surfaces of the fins 120, i.e., directly over the fin sidewalls, and over STI layer 200. The gate dielectric may comprise silicon dioxide, silicon nitride, silicon oxynitride, a high-k dielectric, and/or other suitable material.

As used herein, a high-k material has a dielectric constant greater than that of silicon dioxide. A high-k dielectric may include a binary or ternary compound such as hafnium oxide (HfO₂). Further exemplary high-k dielectrics include, but are not limited to, ZrO₂, La₂O₃, Al₂O₃, TiO₂, SrTiO₃, BaTiO₃, LaAlO₃, Y₂O₃, HfOₓN_{y}, HfSiOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiOₓN_{y}, SiNₓ, a silicate thereof, and an alloy thereof. Each value of x may independently vary from 0.5 to 3, and each value of y may independently vary from 0 to 2.

As used herein, the compounds silicon dioxide and silicon nitride have compositions that are nominally represented as SiO₂ and Si₃N₄, respectively. The terms silicon dioxide and silicon nitride, refer to not only these stoichiometric compositions, but also to oxide and nitride compositions that deviate from the stoichiometric compositions.

The gate dielectric may be deposited by a suitable process such as atomic layer deposition (ALD), chemical vapor deposition (CVD), physical vapor deposition (PVD), thermal oxidation, UV-ozone oxidation, or combinations thereof. The gate dielectric thickness may range from 1 nm to 10 nm, e.g., 1, 2, 4, 6, 8 or 10 nm, including ranges between any of the foregoing values. In various embodiments, the gate dielectric includes a thin layer (e.g., 0.5 nm) of silicon oxide and an overlying layer of high-k dielectric material.

A gate conductor is formed over the gate dielectric. The gate conductor may include a conductive material such as polysilicon, silicon-germanium, a conductive metal such as Al, W, Cu, Ti, Ta, W, Pt, Ag, Au, Ru, Ir, Rh and Re, alloys of conductive metals, e.g., Al—Cu, silicides of one or more conductive metals, e.g., W silicide, and Pt silicide, or other conductive metal compounds such as TiN, TiC, TiSiN, TiTaN, TaN, TaAlN, TaSiN, TaRuN, WSiN, NiSi, CoSi, as well as combinations thereof. The gate conductor may comprise one or more layers of such materials such as, for example, a metal stack including two or more of a barrier layer, work function layer, and conductive fill layer.

The gate conductor may be a conformal layer that is formed over exposed surfaces following deposition of the gate dielectric. The gate conductor can be formed utilizing a conventional deposition process such as, for example, ALD, CVD, metalorganic chemical vapor deposition (MOCVD), molecular beam epitaxy (MBE), PVD, sputtering, plating, evaporation, ion beam deposition, electron beam deposition, laser assisted deposition, or chemical solution deposition. The gate conductor thickness may range from 5 nm to 50 nm, e.g., 5, 10, 15, 20, 30, 40 or 50 nm, including ranges between any of the foregoing values.

Turning to FIGS. 9-14, a gate cut architecture according to a further embodiment is described. The processes and materials used in conjunction with the foregoing embodiment, as described in connection with FIGS. 2-8, may be used in further embodiments.

As seen with reference to FIGS. 9A and 9B, as in the previous embodiment, gate cut opening 515 is formed by directionally etching the sacrificial gate layer 320 using the lithography stack 430 as a masking layer. In the illustrated structure, the sacrificial gate layer 320 is removed selectively with respect to the EG oxide layer 310 such that the EG oxide layer is exposed at the bottom of the opening 515.

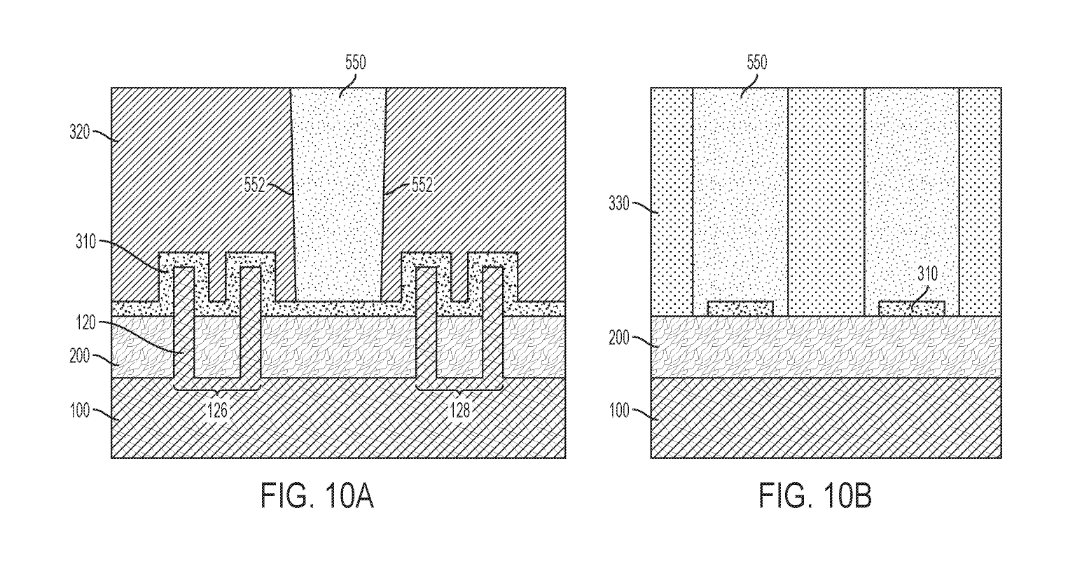

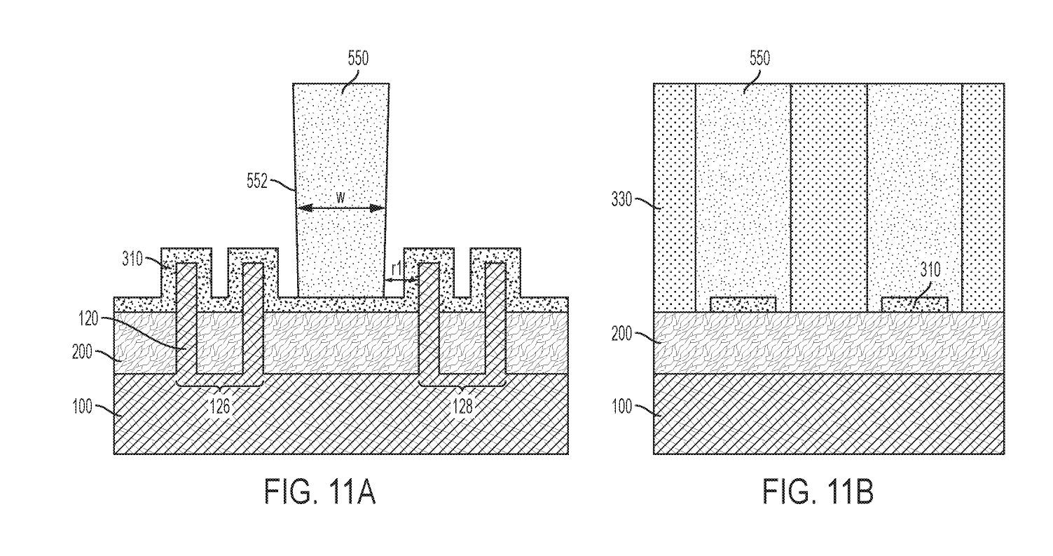

Referring to FIG. 10A and FIG. 10B, dielectric layer 550 is deposited within the gate cut opening 515 directly over the EG oxide layer 310 and then planarized. Referring to FIG. 11A and FIG. 11B, the sacrificial gate 320 is etched selectively leaving the dielectric layer 550 within the gate cut region 510. Exposed surfaces of the dielectric layer 550, including sidewalls 552 are then etched selectively with respect to the EG oxide layer 310 and the STI layer 200.

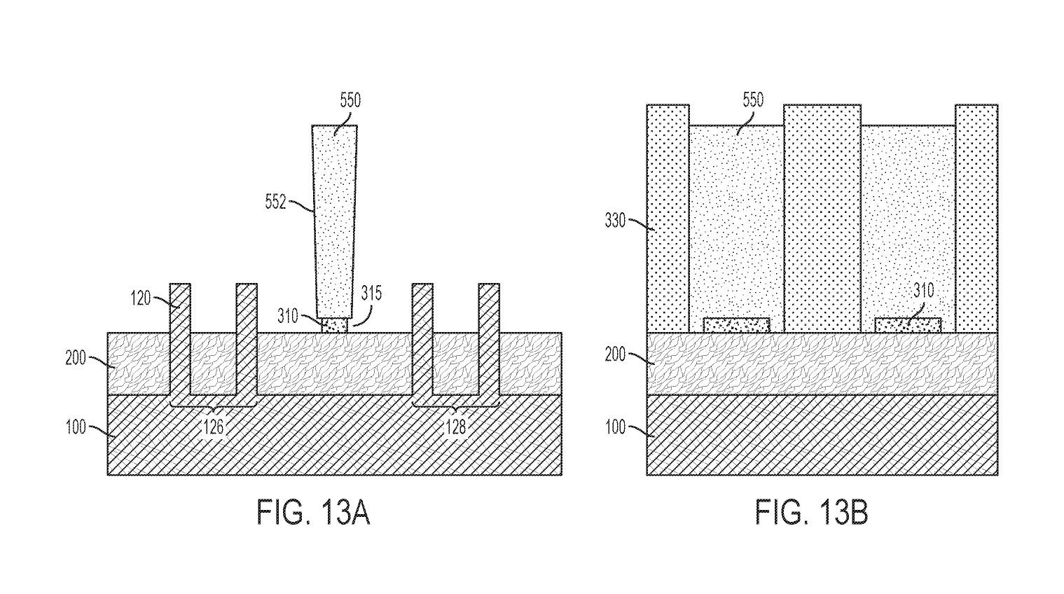

Referring to FIG. 13A and FIG. 13B, a selective oxide etch can be used to remove the EG oxide layer 210 from over the fins. As seen with particular reference to FIG. 13A, portions of the EG oxide layer underlying the dielectric layer 550 may be retained, forming an undercut region 315. Dielectric layer 550 defines an upper surface of the undercut region 315, while STI layer 200 defines a lower surface of the undercut region 315.

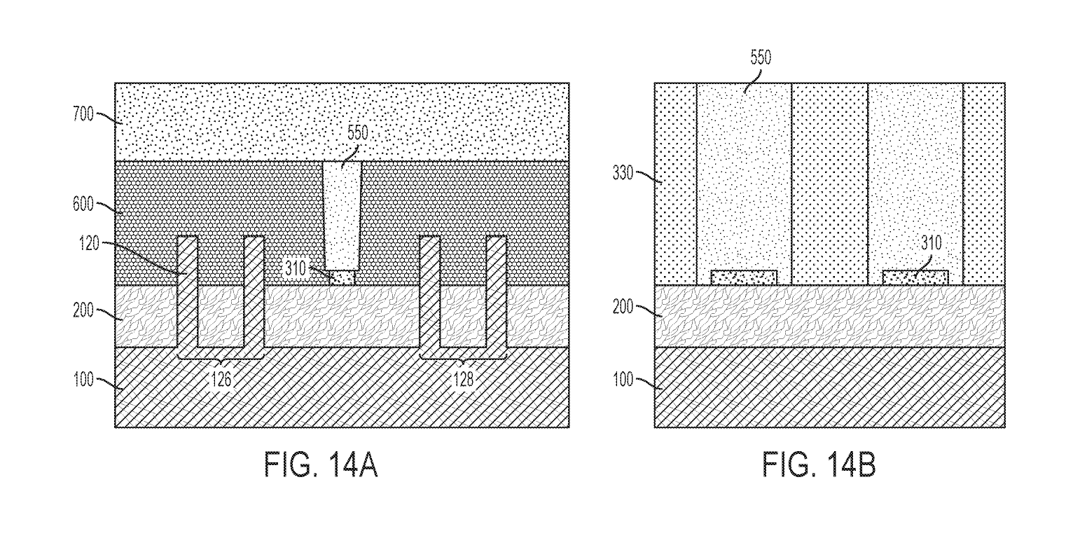

FIG. 14A shows the formation of a replacement gate architecture 600 and capping layer 700 over the fins. In certain embodiments, a portion of the gate architecture may be formed within undercut region 315. FIG. 14B shows the interlayer dielectric 330 and dielectric layer 550 between adjacent fins, i.e., within cut region 510, following formation of the replacement gate 600.

Turning to FIG. 15A and FIG. 15B, a further embodiment includes the formation of a sacrificial barrier layer 311 directly over the EG oxide layer 310 prior to forming the sacrificial gate 320. Referring also to FIG. 1, it will be appreciated that FIG. 15A is taken along the line Y-Y, and FIG. 15B is taken along the line Z-Z.

Sacrificial barrier layer 311 may comprise silicon nitride, titanium nitride or tantalum nitride, for example, and is adapted to protect the EG oxide layer, e.g., during etching to form the gate cut opening 515 and/or during the isotropic etch, i.e., thinning etch, of the dielectric layer 550. In various embodiments, the thickness of the sacrificial barrier layer 311 is 2 to 10 nm, e.g., 2, 4, 6, 8 or 10 nm, including ranges between any of the foregoing values.

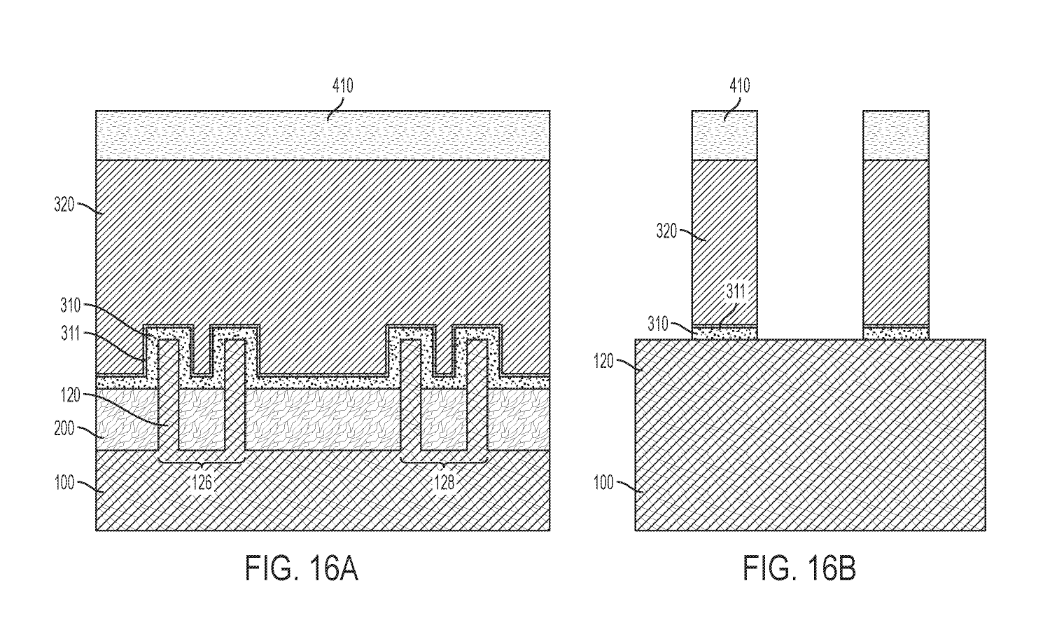

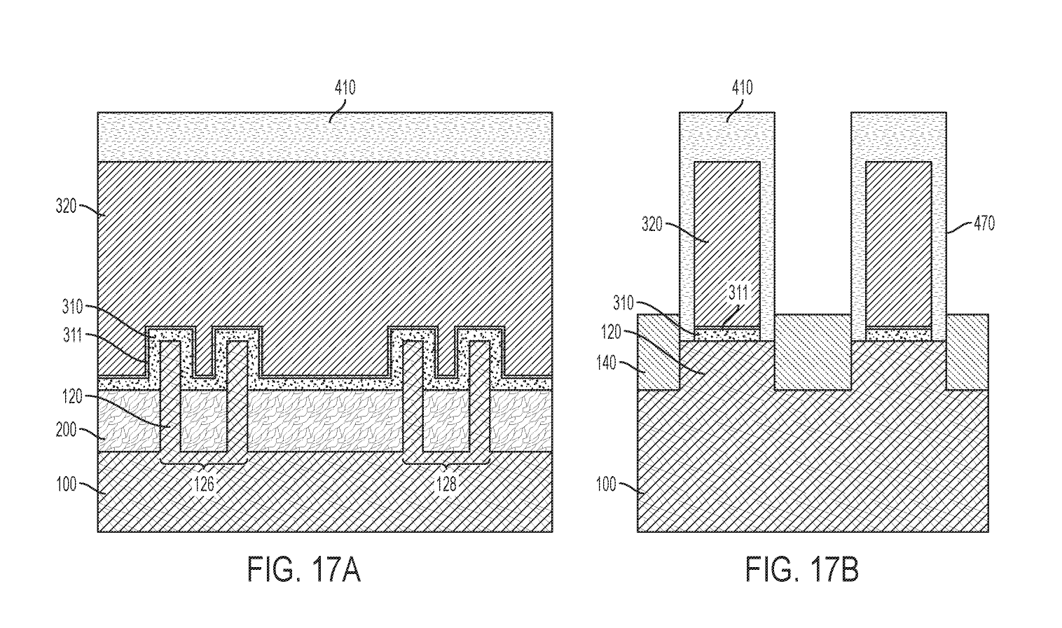

FIG. 16A and FIG. 16B depict the result of patterning and etching steps to form a sacrificial gate 320 over fins 120. FIG. 17A shows the structure of FIG. 16A after the deposition of sidewall spacers 470 over the sacrificial gate and the formation of epitaxial source/drain junctions 140 over source/drain regions of the fin. The sidewall spacers 470 and epitaxial source/drain junctions 140 are shown in FIG. 17B.

Sidewalls spacers 140 are disposed over sidewalls (vertical surfaces) of the sacrificial gate structures 320. Sidewall spacers 140 may be formed by blanket deposition of a spacer material (e.g., using atomic layer deposition) followed by a directional etch such as reactive ion etching (RIE) to remove the spacer material from horizontal surfaces. Suitable sidewall materials include oxides, nitrides and oxynitrides, such as silicon dioxide, silicon nitride, silicon oxynitride, and low dielectric constant (low-k) materials such as amorphous carbon, SiOC, SiOCN and SiBCN, as well as a low-k dielectric material. In certain embodiments, the sidewall spacer 140 thickness is 4 to 20 nm, e.g., 4, 10, 15 or 20 nm, including ranges between any of the foregoing values.

Raised source/drain junctions 140 are disposed over portions of the fins 120 (i.e., source and drain regions) proximate to top surfaces thereof. As known to those skilled in the art, source/drain junctions 140 may be formed by ion implantation or selective epitaxy, optionally using the sacrificial gate structures 320 and sidewall spacers 470 as an alignment mask. For instance, according to various embodiments, source/drain junctions 140 are formed by selective epitaxy into self-aligned cavities that are defined over the fins between the sacrificial gate structures and over-formed sidewall spacers 470. That is, source/drain junctions 140 are formed over source and drain regions of the fins 120 on either side of a channel region, which underlies the sacrificial gate structure 320. During epitaxial growth, the sacrificial barrier layer 311 is covered at least by the sacrificial gate 320 and sidewall spacers 570, and thus is not exposed.

Source/drain junctions 140 may comprise silicon (e.g., Si) or a silicon-containing material such as silicon germanium (SiGe). For instance, SiGe source/drain junctions may be incorporated into a p-MOS device to provide compressive stress to the channel, which can improve carrier mobility.

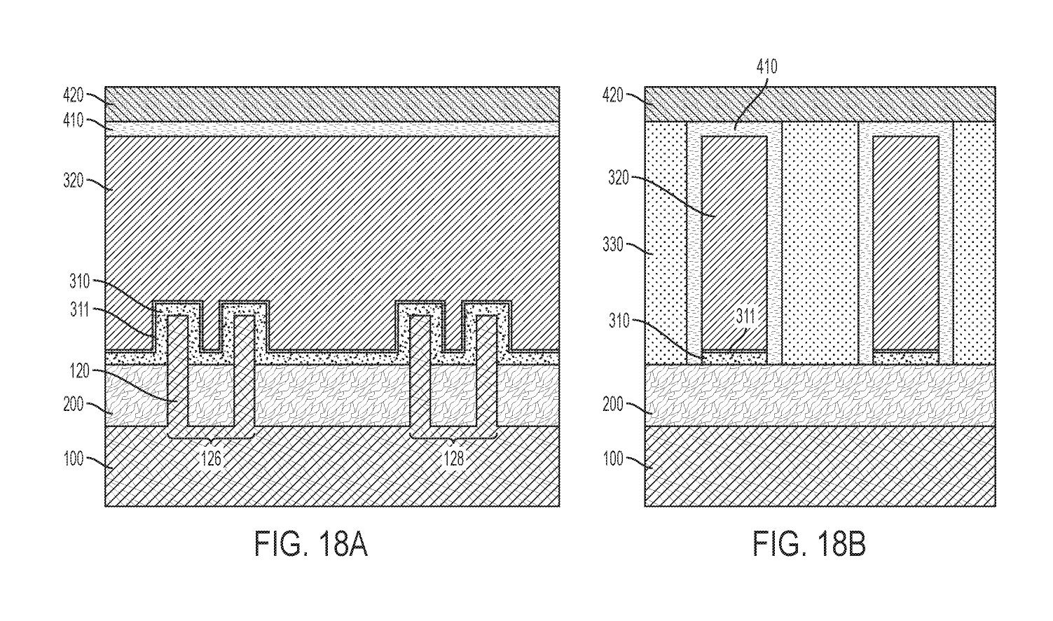

As shown in FIG. 18A and FIG. 18B, an interlayer dielectric (ILD) 330 is deposited over the gate hard mask 410, i.e., between sacrificial gate structure 320. The deposited ILD layer 330 may be polished to remove the excess ILD material and create a planarized structure. A gate cut hard mask 420 is then formed over the top surface of the structure.

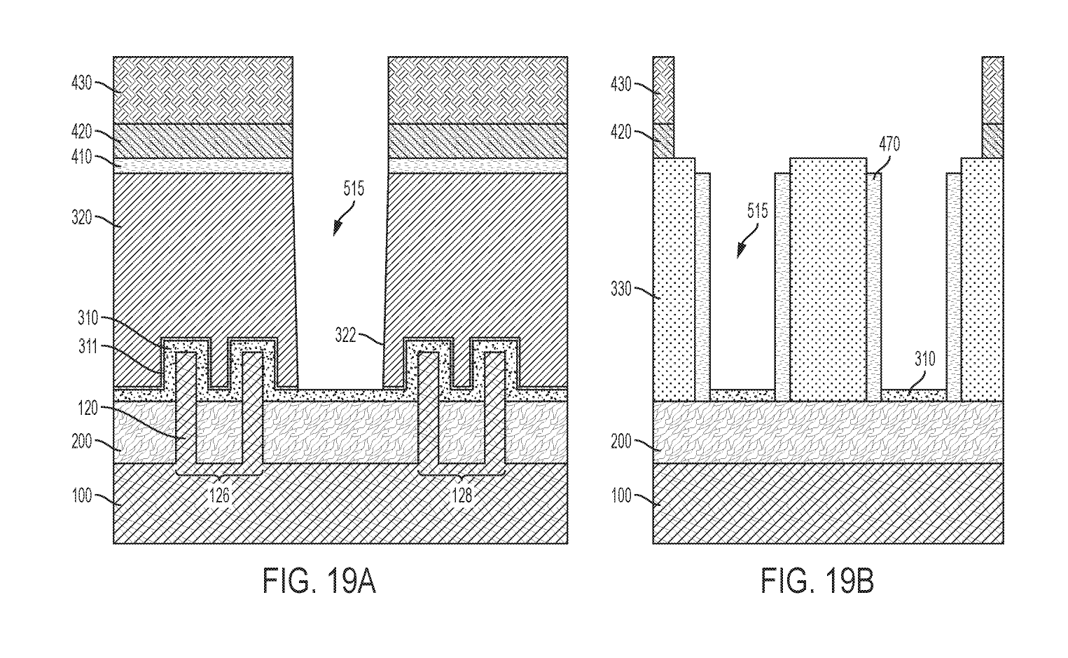

Referring to FIG. 19A and FIG. 19B, after depositing and patterning lithography stack 430, gate cut openings 515 are formed by directionally etching the sacrificial gate layer 320 using the lithography stack 430 as a masking layer. In the illustrated structure, the sacrificial gate layer 320 is removed to form gate cut openings 515. Etching of the sacrificial gate layer 320 may also cause etching partially or entirely through the sacrificial barrier layer 311 and etching partially or entirely through the EG oxide layer 310 at the bottom of the gate cut openings 515. According to certain embodiments, FIG. 19B shows removal of the sacrificial gate 320 and sacrificial barrier layer 311 from within the gate cut openings 515.

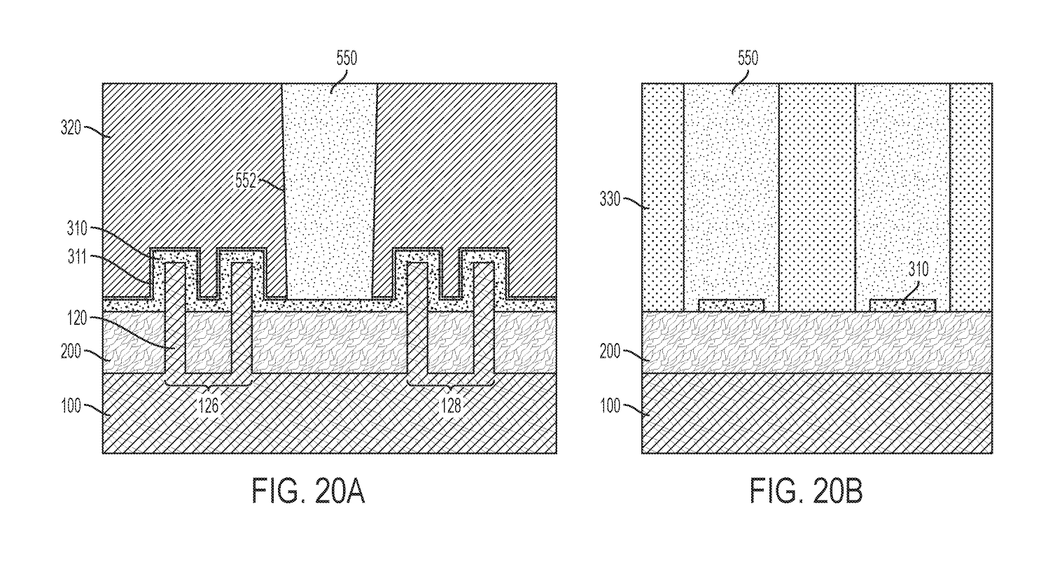

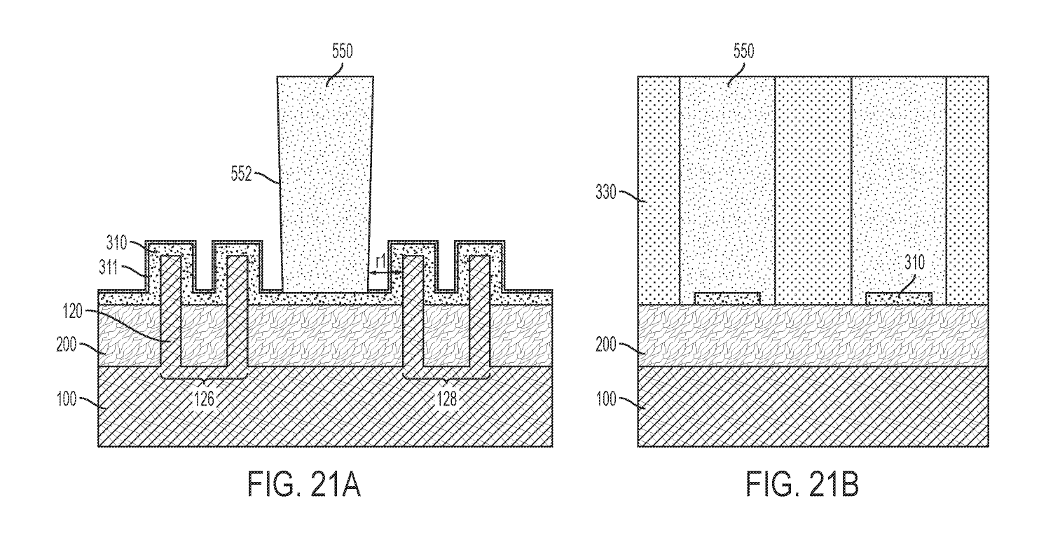

Referring to FIG. 20A and FIG. 20B, dielectric layer 550 is then deposited within the gate cut openings 515 and planarized. Referring to FIG. 21A and FIG. 21B, the sacrificial gate 320 is etched selectively leaving the dielectric layer 550 within the gate cut region 510. At this stage of processing, a distance (r1) between the sidewall 552 of the dielectric layer 550 and an adjacent fin 120 may be less than 20 nm, e.g., 12, 14, 16 or 18 nm, including ranges between any of the foregoing values.

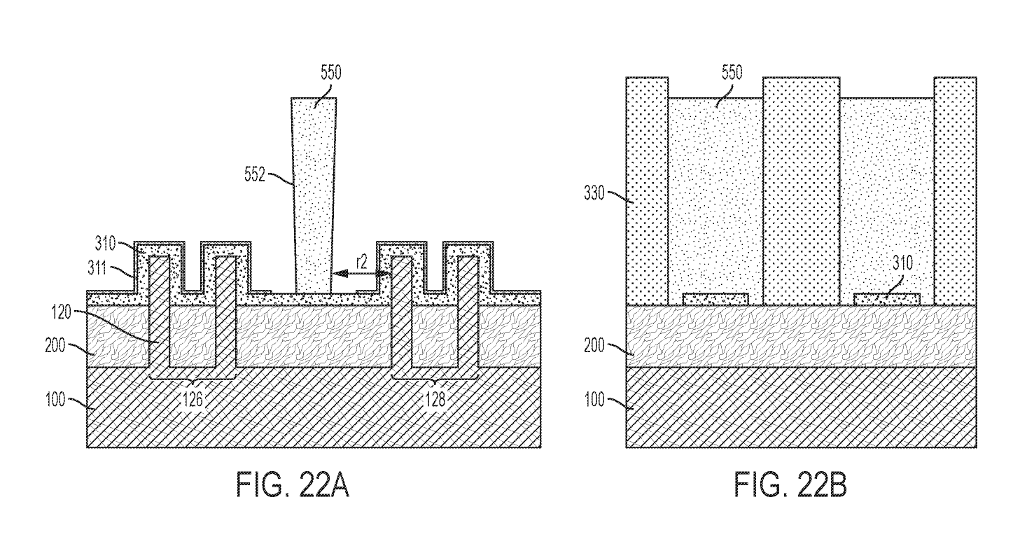

As illustrated in FIG. 22A and FIG. 22B, exposed surfaces of the dielectric layer 550, including sidewall surfaces 552, are etched selectively with respect to the sacrificial barrier layer 311, which decreases width of the dielectric layer and correspondingly increases the gap between the sidewall spacer and an adjacent fin 120 from r1 to r2.

FIG. 22A depicts trimming of the dielectric spacer 550 using a selective isotropic etch to form a thinned dielectric spacer overlying the EG oxide layer 310 within the gate cut region 510. During etching of the dielectric layer 550, sacrificial barrier layer 311 prevents etching of, or damage, to the EG oxide layer 310. In some embodiments, the EG oxide layer 310 is retained with the active device region 124.

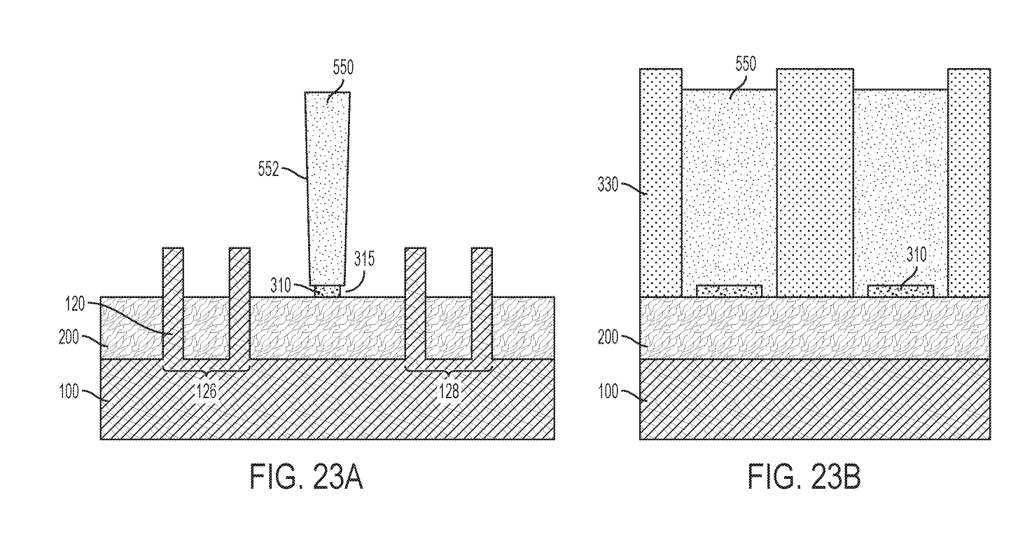

In certain embodiments, referring to FIG. 23A, the sacrificial barrier layer 311 and exposed portions of the EG oxide layer 310 underlying the sacrificial barrier layer 311 are removed. As seen with particular reference to FIG. 23A, portions of the EG oxide layer 310 underlying the dielectric layer 550 may be retained, forming an undercut region 315 into which a gate architecture may be deposited.

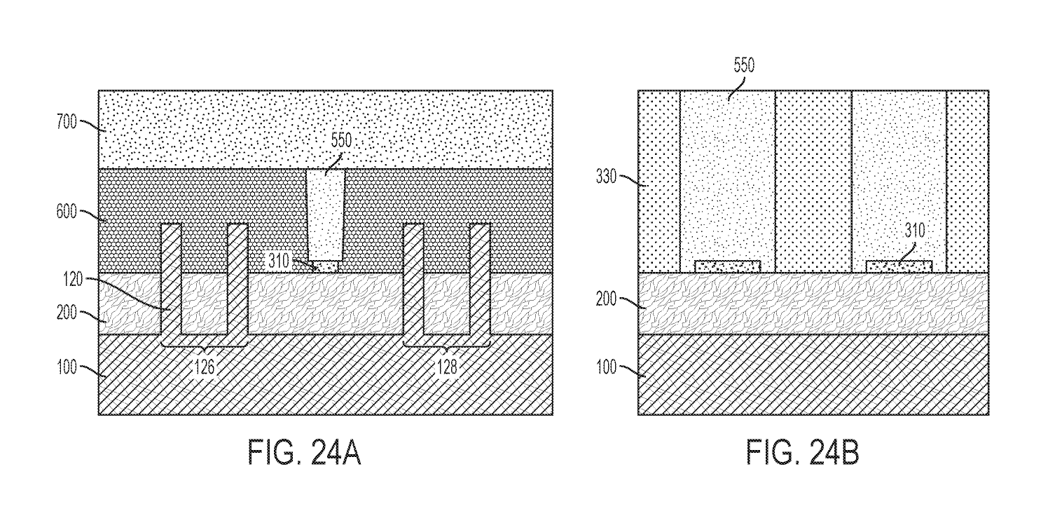

Referring to FIG. 24A and FIG. 24B, a functional gate architecture 600 and overlying capping layer 700 are formed over the fins 120 within the active device region 124. i.e., above STI 200. The functional gate architecture 600 includes a gate dielectric layer and one or more gate conductor layers, which are deposited in succession.

According to various embodiments, as described herein, an opening is formed within the gate cut region of a sacrificial gate. The opening is filled with an etch-selective dielectric layer such that remaining portions of the sacrificial gate can be removed and replaced with a functional gate architecture. Following removal of the remaining portions of the sacrificial gate, and prior to forming the functional gate, at least one lateral dimension of the dielectric layer is etched to decrease its width and correspondingly increase the size of a gap between the dielectric layer and an adjacent fin. The etched dielectric layer is effective to electrically isolate a functional gate formed on one side of the dielectric layer from a functional gate formed on the other side of the dielectric layer. Additional processing may be used to complete the FinFET device, including the formation of contact metallization layers to the gate conductor and source/drain regions of the device.

The disclosed methods enable the formation of sacrificial gate structures, and ultimately functional gate structures, having a small (e.g., less than 15 nm) cut dimension along a longitudinal direction, and a substantially straight (vertical) profile, which may beneficially impact device density and performance. That is, the critical dimension of the gate cut region oriented orthogonal to a length direction of the fins can be decreased to electrically isolate adjacent functional gates without occupying excessive real estate. According to various embodiments, the method includes backfilling a gate cut opening with an etch selective dielectric material. Lateral etching of the dielectric material can be used to increase the distance between the associated gate cut structure and an adjacent fin relative to methods that do not perform such a trimming step using etch selective materials.

As used herein, the singular forms “a,” “an” and “the” include plural referents unless the context clearly dictates otherwise. Thus, for example, reference to a “fin” includes examples having two or more such “fins” unless the context clearly indicates otherwise.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

It will be understood that when an element such as a layer, region or substrate is referred to as being formed on, deposited on, or disposed “on” or “over” another element, it can be directly on the other element or intervening elements may also be present. In contrast, when an element is referred to as being “directly on” or “directly over” another element, no intervening elements are present.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a sacrificial gate that comprises amorphous silicon include embodiments where a sacrificial gate consists essentially of amorphous silicon and embodiments where a sacrificial gate consists of amorphous silicon.

It will be apparent to those skilled in the art that various modifications and variations can be made to the present invention without departing from the spirit and scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

1. A method of forming a semiconductor structure, comprising:
forming a plurality of semiconductor fins over a substrate;
forming a sacrificial gate over the plurality of semiconductor fins;
forming a gate cut opening that extends through the sacrificial gate, wherein a sidewall of the gate cut opening is laterally spaced away from a first one of the semiconductor fins by a first distance;
depositing a single dielectric layer comprising silicon nitride into the gate cut opening;
selectively removing the sacrificial gate with respect to the dielectric layer; and
isotropically etching the dielectric layer to form a gap between the dielectric layer and the first one of the semiconductor fins, wherein the dielectric layer defines an entire sidewall of the gap and a width of the gap extending from the sidewall to the first one of the semiconductor fins is greater than the first distance.

2. The method of claim 1, wherein the sacrificial gate comprises amorphous silicon.

3. The method of claim 1, wherein the gate cut opening extends completely through the sacrificial gate.

4. The method of claim 1, wherein the gate cut opening has substantially vertical sidewalls.

5. The method of claim 1, wherein isotropically etching the dielectric layer decreases a width of the dielectric layer by 20 to 70%.

6. (canceled)

7. The method of claim 1, further comprising forming a shallow trench isolation layer over the substrate and between the semiconductor fins, wherein the dielectric layer is formed directly over the shallow trench isolation layer.

8. The method of claim 7, wherein a portion of the gap extends into a recessed region of the shallow trench isolation layer laterally adjacent to a sidewall of the dielectric layer.

9. The method of claim 1, further comprising forming a conformal oxide layer over the semiconductor fins prior to forming the sacrificial gate.

10. The method of claim 9, wherein the dielectric layer is isotropically etched selectively with respect to the conformal oxide layer.

11. The method of claim 1, wherein the first distance is less than 20 nm.

12. The method of claim 1, further comprising forming a gate dielectric layer over the first one of the semiconductor fins and forming a gate conductor layer over the gate dielectric layer, wherein the gate dielectric layer and the gate conductor layer completely fill the gap.

13. A semiconductor structure, comprising:
a fin disposed over a semiconductor substrate;
a shallow trench isolation layer disposed over the substrate and laterally adjacent to the fin;
a gate stack disposed over the fin and above the shallow trench isolation layer, wherein the gate stack comprises a gate dielectric formed over the fin and a gate conductor formed over the gate dielectric; and
a dielectric layer laterally spaced from the fin and contacting the gate stack, wherein a gap between the dielectric layer and the fin includes a recessed portion of the shallow trench isolation layer.

14. The structure of claim 13, wherein the gate stack fills the gap.

15. The structure of claim 13, wherein the recessed portion of the shallow trench isolation layer is laterally adjacent to a sidewall of the dielectric layer.

16. The structure of claim 13, wherein the dielectric layer comprises silicon nitride.

17. The structure of claim 13, wherein the dielectric layer has substantially vertical sidewalls.

18. The method of claim 1, wherein the dielectric layer consists essentially of silicon nitride.
